(19) United States
(12) Patent Application Publication
(10) Pub. No.: US 2015/0137389 A1
(43) Pub. Date: May 21, 2015

(54) SEMICONDUCTOR PACKAGE

(71) Applicant: Samsung Electronics Co., Ltd., Suwon-si (KR)

(72) Inventor: Maohua DU, Suzhou City (CN)

(21) Appl. No.: 14/549,522

(22) Filed: Nov. 20, 2014

(30) Foreign Application Priority Data
Nov. 21, 2013 (CN) 201310593662.X
Jul. 8, 2014 (KR) 10-2014-0085351

(51) Int. Cl. H01L 25/065; H01L 23/31

(52) U.S. Cl. CPC H01L 25/0657; H01L 23/3135; H01L 2225/06506; H01L 2225/0651; H01L 2225/06527; H01L 2225/06562
USPC 257/777

(57) ABSTRACT

An embodiment includes a semiconductor package comprising: a substrate; a semiconductor chip package unit disposed on the substrate, the semiconductor chip package unit comprising: a first semiconductor chip; a first encapsulating material layer encapsulating the first semiconductor chip; a plurality of connection pads formed on an upper surface of the first encapsulating material layer, at least one of the connection pads being electrically connected to the first semiconductor chip; and a re-wiring layer extending on an upper surface of the semiconductor chip and the upper surface of the first encapsulating material layer, the re-wiring layer being electrically connected to the first semiconductor chip and at least one of the connection pads; and a second semiconductor chip stacked on an upper surface of the semiconductor chip package unit, wherein the second semiconductor chip exposes the connection pads and is electrically connected to one or more of the at least one of the connection pads electrically connected to the first semiconductor chip.

### CROSS-REFERENCE TO RELATED APPLICATIONS

This application claims the benefits of Chinese Patent Application No. 201310593662.X, filed on Nov. 21, 2013 in the Chinese Intellectual Property Office, and Korean Patent Application No. 10-2014-0085351, filed on Jul. 8, 2014 in the Korean Intellectual Property Office, the disclosures of which are incorporated herein in their entirety by reference.

### BACKGROUND

Embodiments relate to a semiconductor device, and more particularly, to a semiconductor stack package in which semiconductor chips are stacked.

With the development of semiconductor technology, a multi-chip package includes multiple semiconductor chips mounted in one package. Currently, the multi-chip package is commonly constructed by vertically stacking bare chips, connecting them to a substrate by means of wire bonding, and then encapsulating the resultant structure with an encapsulating material layer. Such a stack-type semiconductor chip package may have improved mechanical and electrical operation reliability and may be manufactured using a mature manufacturing process.

### SUMMARY

An embodiment includes a semiconductor package comprising: a substrate; a semiconductor chip package unit disposed on the substrate, the semiconductor chip package unit comprising: a first semiconductor chip; a first encapsulating material layer encapsulating the first semiconductor chip; a plurality of connection pads formed on an upper surface of the first encapsulating material layer, at least one of the connection pads being electrically connected to the first semiconductor chip; and a re-wiring layer extending on an upper surface of the semiconductor chip and the upper surface of the first encapsulating material layer, the re-wiring layer being electrically connected to the first semiconductor chip and at least one of the connection pads; and a second semiconductor chip stacked on an upper surface of the semiconductor chip package unit, wherein the second semiconductor chip exposes the connection pads and is electrically connected to one or more of the at least one of the connection pads electrically connected to the first semiconductor chip.

An embodiment includes a semiconductor package comprising: a substrate having an external connection terminal disposed on a lower surface of the substrate; a semiconductor chip package unit disposed on the substrate, the first semiconductor chip package unit comprising: a first semiconductor chip; a first encapsulating material layer encapsulating the first semiconductor chip; and a plurality of connection pads disposed at a side portion of an upper surface of the first encapsulating material layer and that are electrically connected to the first semiconductor chip, the side portion being adjacent to a side of the first semiconductor chip; and at least one second semiconductor chip stacked on an upper surface of the semiconductor chip package unit, wherein the at least one second semiconductor chip exposes the side portion of the upper surface of the first encapsulating material layer and is connected to the connection pads.

An embodiment includes a semiconductor package, comprising: a substrate; a semiconductor chip package unit disposed on the substrate, the first semiconductor chip package unit comprising: a plurality of first semiconductor chips, each first semiconductor chip including a connection member; a first encapsulating material layer encapsulating the first semiconductor chips; a plurality of connection pads; and a re-wiring layer electrically connecting the first semiconductor chips to each other and to the connection pads; and a second semiconductor chip disposed on the semiconductor chip package unit such that the connection pads are exposed, wherein the second semiconductor chip is electrically connected to the connection pads.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an embodiment;

FIG. 2 is a schematic drawing of a signal path of a semiconductor package according to an embodiment;

FIG. 3 is a plan view of a semiconductor chip package unit according to an embodiment;

FIGS. 4 through 7 are cross-sectional views of semiconductor packages according to some embodiments;

FIG. 8 is a flowchart of a method of manufacturing a semiconductor package, according to an embodiment;

FIG. 9 is a schematic block diagram of a memory card including a semiconductor package according to an embodiment;

FIG. 10 is a schematic block diagram of an electronic system including a semiconductor package according to an embodiment;

FIG. 11 is a top view of a solid state drive (SSD) device including a semiconductor package according to an embodiment is applied; and

FIG. 12 is a perspective view of an electronic device including a semiconductor package according to an embodiment.

### DETAILED DESCRIPTION OF THE EMBODIMENTS

Hereinafter, embodiments will be described more fully with reference to the accompanying drawings, in which particular embodiments are shown.

Embodiments may, however, take many different forms and should not be construed as limited to the particular embodiments set forth herein. Rather, these embodiments are provided so that this disclosure will be thorough and complete, and will fully convey the scope to those of ordinary skill in the art. In addition, in the drawings, the thicknesses or sizes of layers are exaggerated for convenience and clarity of description.

When it is described through the specification that a certain element, such as a layer, a region, or a substrate, is located “on” or “connected” to another element, it may be understood that the certain element may be located “on” or “connected” to another element directly or via another intervening element. In contrast, when a certain element is “directly located on” or “directly connected” to another element, it should be understood that there is no intervening. Like reference numerals denote like elements. As used herein, the term “and/or” includes any and all combinations of one or more of the associated listed items.

Although terms, such as ‘first’ and ‘second’, are used to describe various members, regions, layers, and/or parts, these members, regions, layers, and/or parts are not limited by these terms. These terms are used to distinguish a certain member, region, layer, or part from another member, region, layer, or part. Therefore, a first member, region, layer, or part can be named a second member, region, layer, or part and include the same attributes as when labeled with the term “first.”

The relative terms, such as “on” or “above” and “below” or “under,” can be used herein for describing a relationship of certain elements with respect to other elements as illustrated in the drawings. The relative terms are intended to include other orientations of a device in addition to the particular orientation described in the drawings. For example, if a device is turned over in the drawings, elements described as being on upper surfaces of other elements would now be on lower surfaces of the other elements. Therefore, for example, the term “on” may include both directions of “below,” “above,” “on the side,” or the like depending on a particular orientation of the drawings.

The terminology used in the application is used only to describe specific embodiments and may not limit other embodiments. An expression in the singular includes an expression in the plural unless they are clearly different from each other in context. It will be further understood that the terms “comprises” and/or “comprising,” when used in this specification, specify the presence of stated shapes, integers, steps, operations, members, elements, and/or a group thereof, but do not exclude the presence or addition of one or more other shapes, integers, steps, operations, members, elements, and/or groups thereof.

Embodiments will now be described more fully with reference to the accompanying drawings, in which particular embodiments are shown. In the drawings, modifications of the shown shapes can be predicted according to, for example, a manufacturing technique and/or tolerance. Therefore, it should not be understood that the embodiments are limited to the specific shapes of regions illustrated in the specification, and the embodiments should include, for example, a change in shapes caused according to manufacturing.

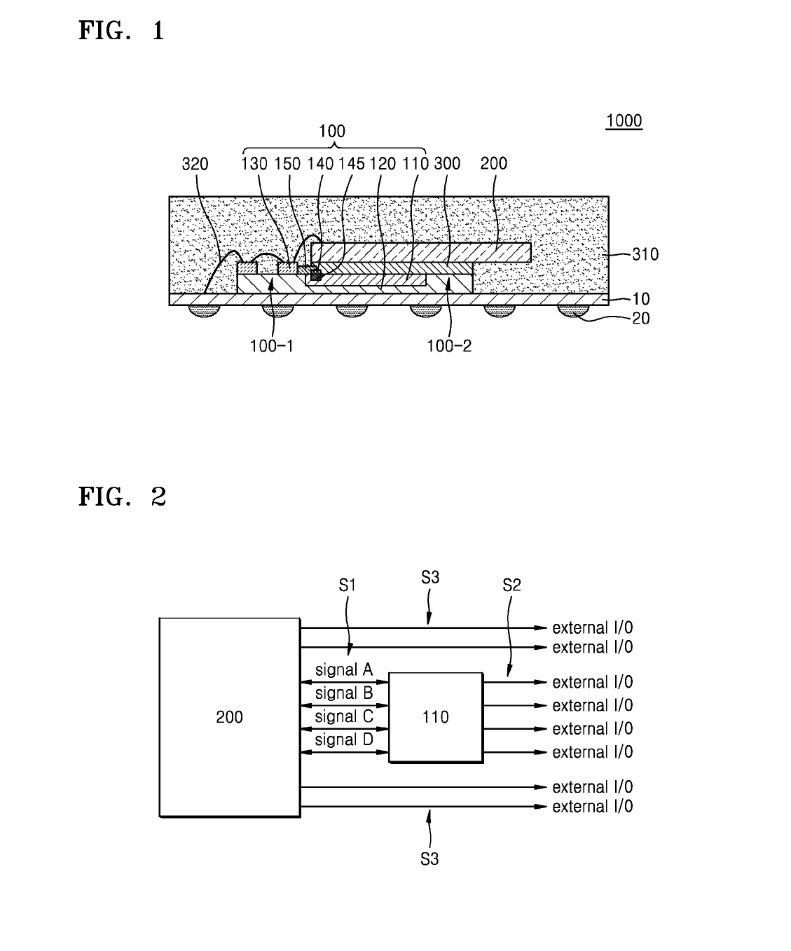

FIG. 1 is a cross-sectional view of a semiconductor package 1000 according to an embodiment. Referring to FIG. 1, the semiconductor package 1000 may include a substrate 10, an external connection member 20 formed on a lower surface of the substrate 10, a semiconductor chip package unit 100, a second semiconductor chip 200, a second encapsulating material layer 310, and a bonding wire 320. The semiconductor chip package unit 100 includes a first semiconductor chip 110, a first encapsulating material layer 120, a plurality of connection pads 130, a connection terminal 140, and a re-wiring layer 150.

The substrate 10 is a supporting substrate on which the semiconductor chip package unit 100 is mounted and may include the external connection member 20 formed on the lower surface of the substrate 10. The substrate 10 may include a ceramic substrate, a printed circuit board (PCB), an organic substrate, an interposer substrate, or any substrate on which a semiconductor chip may be mounted. In some cases, the substrate 10 may include an active wafer. In one embodiment, the substrate 10 may be a PCB.

The external connection member 20 may be formed on the lower surface of the substrate 10. The entire semiconductor package 1000 may be mounted on an external system substrate or main board via the external connection member 20. The external connection member 20 may be formed of a conductive material including, for example, copper (Cu), aluminum (Al), silver (Ag), tin (Sn), gold (Au), solder, combinations of such materials, or the like. However, the material of the external connection member 20 is not limited these particular examples. The external connection member 20 may include multiple layers or a single layer. The external connection member 20 may be formed as a Pin Grid Array (PGA), a Ball Grid Array (BGA), a Micro Pillar Grid Array (MPGA), or the like. In one embodiment, the external connection member 20 may be a BGA. However, embodiments are not limited thereto. For example, the substrate 10 may include a conductive protruding portion that is formed on the lower surface of the substrate 10, and the first and second semiconductor chips 110 and 200 of the semiconductor package 1000 may be electrically connected to an external device via the conductive protruding portion. Additionally, the substrate 10 may include a lead frame on which the first semiconductor chip 110 and the second semiconductor chip 200 are mounted, and the first semiconductor chip 110 and the second semiconductor chip 200 may be electrically connected to an external device via the lead frame.

The semiconductor chip package unit 100 is mounted on the substrate 10 and may include the first semiconductor chip 110, the first encapsulating material layer 120, connection pads 130, the connection terminal 140, and the re-wiring layer 150, as described above. An adhesive layer (not illustrated) may be formed between the semiconductor chip package unit 100 and an upper surface of the substrate 10. In one embodiment, the semiconductor chip package unit 100 may further include a dielectric layer 300.

The first semiconductor chip 110 may be a logic semiconductor chip. The first semiconductor chip 110 may be a microprocessor, a central processing unit (CPU), a memory controller chip, an application specific integrated circuit (ASIC), a programmable logic device, combinations of such devices, or the like. In some embodiments, the first semiconductor chip 110 may be an application processor that is used in a mobile phone or a smart phone. In some embodiments, the first semiconductor chip 110 may be a memory controller chip.

The first semiconductor chip 110 may be encapsulated by the first encapsulating material layer 120. The encapsulating material layer 120 may protect the first semiconductor chip 110 from the external environment, for example, moisture, impurities, and the like. The first encapsulating material layer 120 may be formed by an injection molding process. In one embodiment, the first encapsulating material layer 120 may be formed so that an upper surface of the first encapsulating material layer 120 is substantially coplanar with an upper surface of the first semiconductor chip 110. However, in other embodiments, the upper surfaces of the first encapsulating material layer 120 and the first semiconductor chip 110 may be offset. In some other embodiments, the first encapsulating material layer 120 may be formed so that the upper surface of the first encapsulating material layer 120 only exposes a semiconductor chip connection member 145.

The connection pads 130 may be formed on the upper surface of the first encapsulating material layer 120. The connection pads 130 may be formed on the upper surface of the first encapsulating material layer 120 by using various methods. For example, the connection pads 130 may be formed by depositing a metal material layer including Cu, Al, Ag, Sn, Au, solder, combinations of such materials, or the like, and then patterning the metal material layer. However, embodiments are not limited thereto, and the connection pads 130 may be formed by using a pulse plating method, a direct current (DC) plating method, or other deposition techniques.

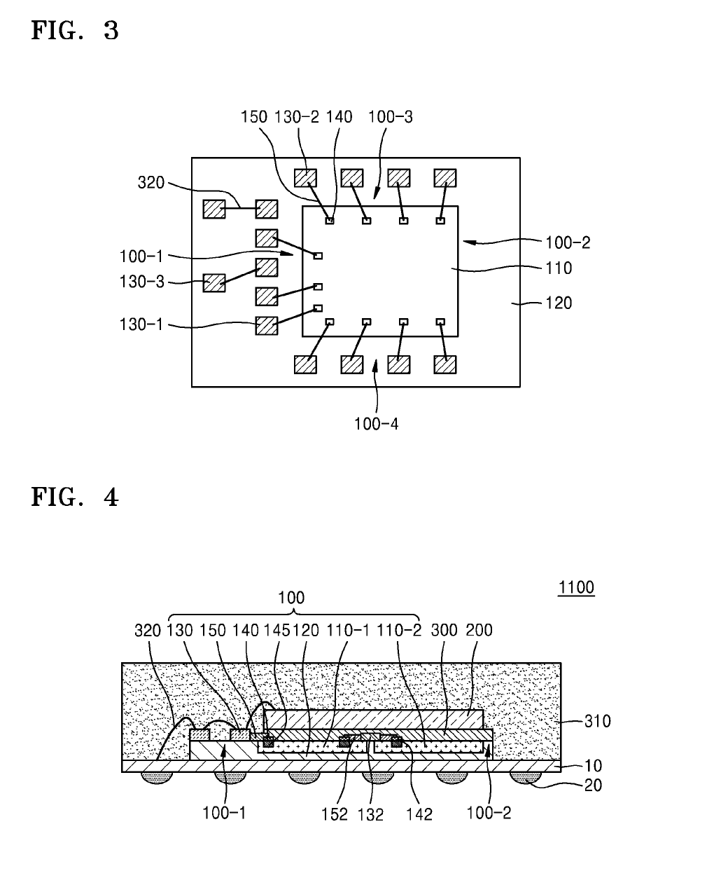

The connection pads 130 may be formed in a first area 100-1, which is adjacent to a surface of the first semiconductor chip 110, of the upper surface of the first encapsulating material layer 120. However, embodiments are not limited thereto. In some other embodiments, the connection pads 130 may be formed in the first area 100-1, a third area 100-3, and a fourth area 100-4 (refer to FIG. 3), which are adjacent to side portions of the first semiconductor chip 110, of the upper surface of the first encapsulating material layer 120.

The connection terminal 140 may be formed at one side of the upper surface of the first semiconductor chip 110 and may be electrically connected to the connection pads 130 via the re-wiring layer 150. The connection terminal 140 may Cu, Al, Ag, Sn, Au, solder, combinations of such materials, or the like. The connection terminal 140 may be formed by using a pulse plating method, a DC plating method, or other deposition techniques. However, the material of the connection terminal 140 and a method of forming the connection terminal 140 are not limited thereto.

The re-wiring layer 150 is configured to electrically connect the first semiconductor chip 110 to the connection pads 130 and may extend on a portion of the upper surface of the first semiconductor chip 110 and a portion of the upper surface of the first encapsulating material layer 120. For example, the re-wiring layer 150 may be formed by depositing a metal material layer on the portion of the upper surface of the first semiconductor chip 110 and the portion of the upper surface of the first encapsulating material layer 120 and then patterning the deposited metal material layer. In one embodiment, the re-wiring layer 150 and the connection pads 130 may be simultaneously formed by the same depositing and patterning process. That is, the re-wiring layer 150 and the connection pads 130 may be simultaneously formed by depositing a metal material layer on the upper surfaces of the first semiconductor chip 110 and the first encapsulating material layer 120 and then patterning the deposited metal material layer.

The semiconductor package 1000 may further include the dielectric layer 300. The dielectric layer 300 may cover a portion of the upper surface of the first semiconductor chip 110 and a portion of the upper surface of the first encapsulating material layer 120 but may not cover the connection pads 130 so that the connection pads 130 are exposed. In one embodiment, the dielectric layer 300 may include openings exposing the connection pads 130. The dielectric layer 300 may cover the re-wiring layer 150. The dielectric layer 300 may prevent the first semiconductor chip 110 from being unexpectedly connected electrically to other elements or an external device and may also protect from unintended electrical connection between the first semiconductor chip 110 and the connection pads 130.

The dielectric layer 300 may include Polyimide (PI), PCB, a combination thereof, or the like. In one embodiment, the dielectric layer 300 may be formed by forming a PI layer on a PCB layer, coating an adhesive on the PCB layer, spinning the PI layer and the PCB layer so that the adhesive is uniformly coated, and then curing the adhesive layer by using heat or UV rays. In addition, the dielectric layer 300 may also be formed by laminating a thin film including a PI layer and a PCB layer and then curing the thin film by using heat or UV rays.

The second semiconductor chip 200 may be stacked on the semiconductor chip package unit 100. The second semiconductor chip 200 may not cover the connection pads 130 so that the connection pads 130 are exposed. In one embodiment, an adhesive layer may be formed between a lower surface of the second semiconductor chip 200 and an upper surface of the semiconductor chip package unit 100. As illustrated in FIG. 1, the second semiconductor chip 200 may be stacked on the semiconductor chip package unit 100 in an offset manner, thereby exposing the connection pads 130 on a portion of the upper surface of the first encapsulating material layer 120 that is adjacent to one side of the first semiconductor chip 110. That is, a side of the semiconductor chip package unit 100 and a side of the second semiconductor chip 200 may not be vertically aligned. However, embodiments are not limited thereto, and in other embodiments, the second semiconductor chip 200 may be stacked in other manners. Referring to FIG. 4, the second semiconductor 200 may be stacked closer to a center of the upper surface of the semiconductor chip package unit 100 and may expose the connection pads 130 surrounding the first semiconductor chip 110.

Referring back to FIG. 1, the second semiconductor chip 200 may be electrically connected to some of the connection pads 130. In one embodiment, the second semiconductor chip 200 may be electrically connected to connection pads 130 connected to the first semiconductor chip 110 from among the connection pads 130. Referring to FIG. 3, when the first semiconductor chip 110 is electrically connected to a first connection pad 130-1 and a second connection pad 130-2 through the re-wiring layer 150 and not electrically connected to a third connection pad 130-3, the second semiconductor chip 200 may be electrically connected to the first connection pad 130-1 and the third connection pad 130-3 and not electrically connected to the second connection pad 130-2. The third connection pad 130-3 may be electrically connected to the substrate 10 through the bonding wires 320.

Referring back to FIG. 1, the second semiconductor chip 200 and the first semiconductor chip 110 may be the same kind of semiconductor chips or different kinds of semiconductor chips. The second semiconductor chip 200 may include an active wafer or an interposer substrate. The second semiconductor chip 200 may be a semiconductor memory device. The second semiconductor chip 200 may include DRAM, SRAM, flash memory, EEPROM, PRAM, MRAM, RRAM, or other memory devices. In one embodiment, the second semiconductor chip 200 may be a flash memory chip. The second semiconductor chip 200 may have a different size than that of the first semiconductor chip 110. The second semiconductor chip 200 and the first semiconductor chip 110 may be different kinds of semiconductor chips having different functions. As described above, in an embodiment, the first semiconductor chip 110 may be a memory controller chip, and the second semiconductor chip 200 may be a flash memory chip. However, embodiments are not limited thereto.

The second encapsulating material layer 310 may be formed on the substrate 10 to encapsulate the semiconductor chip package unit 100 and the second semiconductor chip 200. The second encapsulating material layer 310 may protect the substrate 10, the semiconductor chip package unit 100, and the second semiconductor chip 200 from an external environment such as moisture, impurities and the like. In one embodiment, the second encapsulating material layer 310 may be formed of the same material as that of the first encapsulating material layer 120. The second encapsulating material layer 310 may be formed by an injection molding process.

A signal path of the semiconductor package 1000 will be described in detail with reference to FIGS. 1-3. FIG. 2 is a schematic drawing of the signal path of the semiconductor package 1000 according to an exemplary embodiment, and FIG. 3 is a plan view of the semiconductor chip package unit 100 according to an embodiment.

Referring to FIGS. 1-3, the semiconductor package 1000 may have first to third signal paths S1, S2, and S3. In the illustration of FIG. 3, the bonding wires 320 coupled to the substrate or the second semiconductor chip 200 are not illustrated; however, examples may be seen in FIG. 1. The first signal path S1 is a path in which an electrical signal is sequentially transmitted through the first semiconductor chip 110, the re-wiring layer 150, the first connection pad 130-1, the bonding wire 320, and the second semiconductor chip 200. The second signal path S2 is a path in which an electrical signal is sequentially transmitted through the first semiconductor chip 110, the re-wiring layer 150, the second connection pad 130-2, the bonding wire 320, the substrate 10, and the external connection member 20. The third signal path S3 is a path in which an electrical signal is sequentially transmitted through the second semiconductor chip 200, the bonding wire 320, the third connection pad 130-3, the bonding wire 320, the substrate 10, and the external connection member 20.

The first semiconductor chip 110 and the second semiconductor chip 200 may be configured to transmit signals A to D through the first signal path S1 without using the substrate 10. In an embodiment, the second semiconductor chip 200 may be a NAND flash memory chip, and the first semiconductor chip 110 may be a memory controller chip.

Referring to FIG. 3, the connection pads 130 may be formed in a first area 100-1, a third area 100-3, and a fourth area 100-4, which are adjacent to three sides of the first semiconductor chip 110, of the upper surface of the first encapsulating material layer 120. In an embodiment, the connection pads 130 may be used as a connection member and may be electrically connected to the first semiconductor chip 110. The connection pads 130 may include the first connection pad 130-1, the second connection pad 130-2, and the third connection pad 130-3. The first semiconductor chip 110 may be electrically connected to the first connection pad 130-1 and the second connection pad 130-2 through the re-wiring layer 150 and may not be connected to the third connection pad 130-3.

As described above, the first semiconductor chip 110 and the second semiconductor chip 200 may transmit signals therebetween without using the substrate 10, and thus, an electrical distance of the signal path between a NAND flash memory chip and a memory controller chip may be minimized, thereby increasing transmission speed, stabilizing signal transmission, and thus improving the operation reliability and performance of an electrical device including the semiconductor package 1000.

As described above, various signal paths may pass through various combinations of bond wires 320, connection pads 130, and rewiring layer 150. Although some examples have been given, in other embodiments, any combination of bond wires 320, connection pads 130, and rewiring layer 150 may be used to form a connection among the first semiconductor chip 110, the second semiconductor chip 200, and the substrate 10, between the first semiconductor chip 110 and the second semiconductor chip 200, between the first semiconductor chip 110 and the substrate 10, and between the second semiconductor chip 200 and the substrate 10.

FIGS. 4 through 7 are cross-sectional views of semiconductor packages 1100 to 1400 according to some other embodiments. The following description will focus on differences between the semiconductor packages 1100 to 1400 and the semiconductor package 1000 shown in FIG. 1 and repeated descriptions of same elements will be omitted.

Referring to FIG. 4, the semiconductor package 1100 may include multiple first semiconductor chips 110-1 and 110-2 and a first encapsulating material layer 120 encapsulating the first semiconductor chips 110-1 and 110-2. In an embodiment, of the first semiconductor chips 110-1 and 110-2, the first semiconductor chip 110-1 may be a memory controller chip and the first semiconductor chip 110-2 may be a DRAM chip. The first semiconductor chip 110-1 and the first semiconductor chip 110-2 may be electrically connected to some of multiple connection pads 130, thereby being electrically connected to a substrate 10 and/or a second semiconductor chip 200. The first semiconductor chips 110-1 and 110-2 may be electrically connected to the same connection pads 132, and thus may be electrically connected to each other. The first semiconductor chip 110-1 and the second semiconductor chip 110-2 may be connected to the connection pads 132 through a connection terminal 142 and a re-wiring layer 152, formed on upper surfaces of the first semiconductor chips 110-1 and 110-2, and thus may be electrically connected to each other.

The first encapsulating material layer 120 may be formed to expose the upper surfaces of the first semiconductor chips 110-1 and 110-2 and the connection pads 132 connecting the first semiconductor chip 110-1 to the first semiconductor chip 110-2. Thus, the first semiconductor chip 110-1 and the first semiconductor chip 110-2 may be electrically connected to the substrate 10 and the second semiconductor chip 200 through the connection pads 132 and the re-wiring layer 150.

The second semiconductor chip 200 may be disposed adjacent to a second area 100-2, which is opposite to the first area 100-1 of the semiconductor chip package unit 100, to expose the connection pads 130 formed in the first area 100-1 of the upper surface of the semiconductor chip package unit 100. In addition, a side of the second semiconductor chip 200 may, but need not be vertically aligned to a side of the first semiconductor chip 110-1, a side of the first semiconductor chip 110-2, and/or a side of the first encapsulating material 120.

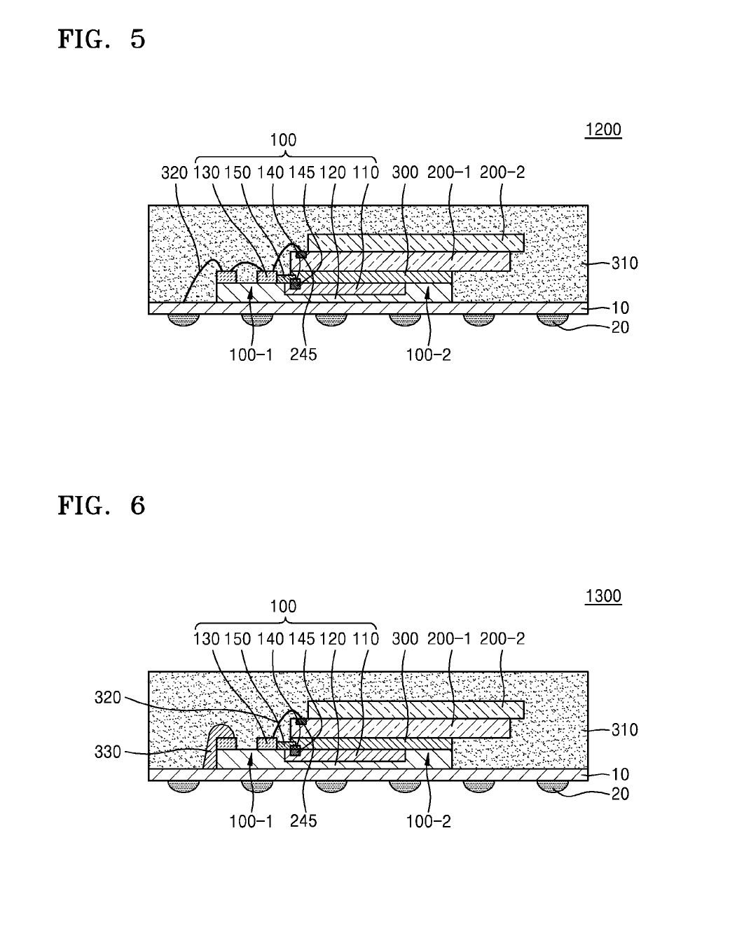

Referring to FIG. 5, the semiconductor package 1200 may include multiple second semiconductor chips 200-1 and 200-2. Although two second semiconductor chips 200-1 and 200-2 are stacked in FIG. 5 for convenience of explanation, other embodiments may include more second semiconductor chips 200.

The lowest second semiconductor chip 200, i.e., the second semiconductor chip 200-1 of the second semiconductor chips 200-1 and 200-2, is mounted adjacent a first area 100-1 of an upper surface of a semiconductor chip package unit 100 and exposes multiple connection pads 130. The second semiconductor chip 200-2 may be stacked on the upper surface of the second semiconductor chip 200-1 and offset towards a second area 100-2 to expose a connection member 245 formed on the upper surface of the second semiconductor chip 200-1. As illustrated in FIG. 5, the second semiconductor chips 200-1 and 200-2 may be stacked on the semiconductor chip package unit 100 in an offset manner; however, in other embodiments, the second semiconductor chips 200 may not be offset.

The second semiconductor chips 200-1 and 200-2 may be electrically connected to some of the connection pads 130. In an embodiment, the second semiconductor chip 200-1 may be electrically connected to the same connection pads 130 to which the first semiconductor chip 110 is connected.

The second semiconductor chip 200-2 may be electrically connected to the second semiconductor chip 200-1 through a connection member 245 of the second semiconductor chip 200-1 under the second semiconductor chip 200-2, and the second semiconductor chip 200-1 may be electrically connected to the first semiconductor chip 110 through a connection member 145 of the first semiconductor chip 110 under the second semiconductor chip 200-1. Accordingly, the second semiconductor chips 200-1 and 200-2 may receive substantially the same electrical signal from the first semiconductor chip 110. In other words, in the semiconductor package 1200 according to an embodiment, where the stacked semiconductor chips share the same electrical signals, a common signal path may be formed by the common connection pads 130. In an embodiment, the second semiconductor chips 200-1 and 200-2 may be NAND flash memory chips and the first semiconductor chip 110 may be a memory controller chip. In this case, a common signal path between the memory controller chip and the NAND flash memory chips may be formed by the common connection pads 130, thereby increasing transmission speed, stabilizing signal transmission and thus improving the reliability and operation performance of a semiconductor device.

In the semiconductor chip packages 1000 to 1200 illustrated in FIGS. 1 to 5, the semiconductor chip package unit 100 and the second semiconductor chip 200 or 200-1 and 200-2 are stacked on the substrate 10, and the semiconductor chip package unit 100, the second semiconductor chip 200 or 200-1 and 200-2, and the substrate 10 may be electrically connected to each other by using the bonding wire 320.

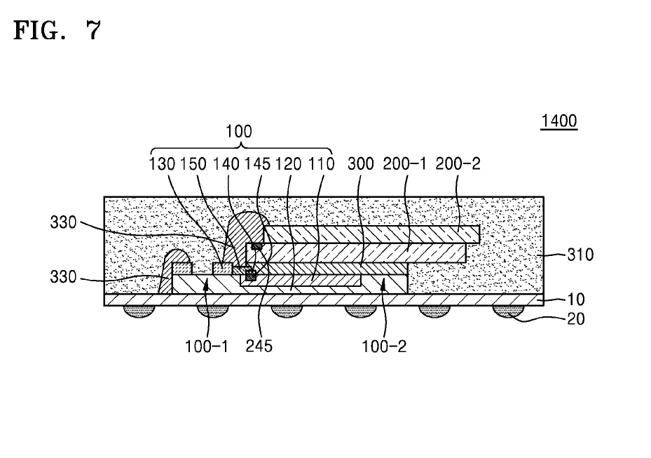

However, in the semiconductor chip packages 1300 and 1400 illustrated in FIGS. 6 and 7, a substrate 10, a semiconductor chip package unit 100, and second semiconductor chips 200-1 and 200-2 may be electrically connected to each other by using a conductive adhesive 330 instead of the bonding wire 320. Referring to FIG. 6, multiple connection pads 130 of the semiconductor chip package unit 100 may be electrically connected to the substrate 10 through the conductive adhesive 330. Referring to FIG. 7, multiple connection pads 130 of the semiconductor chip package unit 100 may be electrically connected to the substrate 10 through the conductive adhesive 330, and the second semiconductor chips 200 may also be electrically connected to the connection pads 130 through the conductive adhesive 330.

In an embodiment, the conductive adhesive 330 may be a conductive adhesive including silver (Ag). However, in other embodiments, the conductive adhesive 330 may include other conductive materials. The conductive adhesive 330 may be formed using a dispensing and curing process. In one embodiment, the conductive adhesive 330 may be formed of an epoxy resin including conductive particles. The conductive particles may include conductive materials such as silver, gold, copper, combinations of such materials, or the like. In one embodiment, the conductive adhesive 330 may be in a gel state at room temperature. In order to form the conductive adhesive 330, an adhesive material including conductive particles is extruded out of a dispenser by driving a motor, is applied on a surface of an object along a preset moving path to form a pattern, and then is cured by heating.

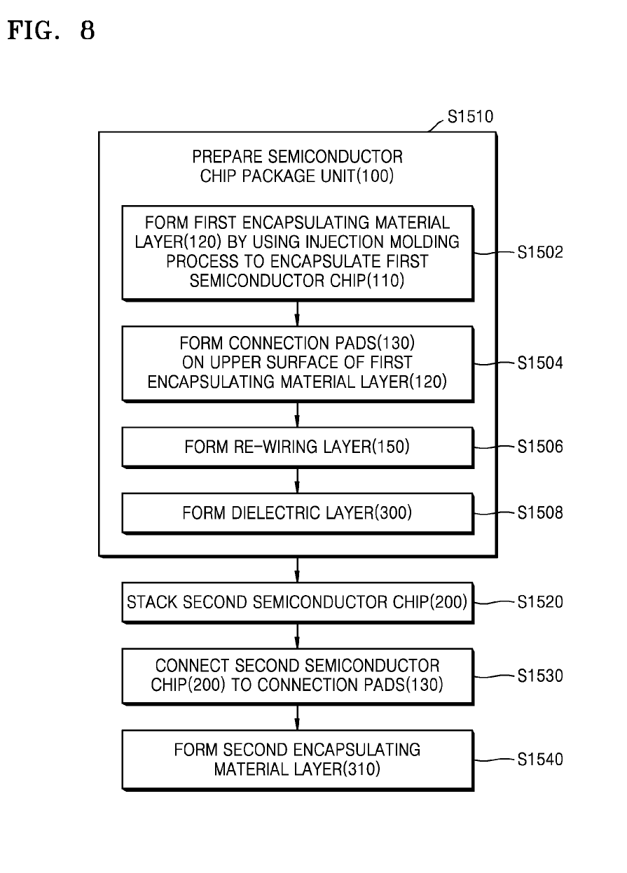

FIG. 8 is a flowchart of a method of manufacturing a semiconductor package, according to an embodiment. The semiconductor package may be any one of the semiconductor packages 1000 to 1400. Below, the method is described in relation to the semiconductor packages 1000 to 1400.

Referring to FIG. 8, first, a semiconductor chip package unit 100 is prepared (Operation S1510). The semiconductor chip package unit 100 may include a first semiconductor chip 110, a first encapsulating material layer 120, and multiple connection pads 130.

The semiconductor chip package unit 100 may be manufactured by using techniques generally used to manufacture a semiconductor package. The semiconductor chip package unit 100 may be a package including an exposed connection member 145 of the first semiconductor chip 110. In one embodiment, the first encapsulating material layer 120 may be formed using an injection molding process to encapsulate the first semiconductor chip 110 and to expose an upper surface of the first semiconductor chip 110 and a connection member 145 formed on the upper surface of the first semiconductor chip 110 (Operation S1502).

The connection pads 130 may be formed by depositing a metal material layer on an upper surface of the first encapsulating material layer 120 and patterning the deposited metal material layer, after an encapsulation member structure of the first semiconductor chip 110 and the first encapsulating material layer 120 is formed (Operation S1504). In addition, a re-wiring layer 150 may be formed by depositing a metal material layer on the upper surface of the first semiconductor chip 110 and the upper surface of the first encapsulating material layer 120 and patterning the deposited metal material layer (Operation S1506). As a result, at least one of the connection pads 130 may be electrically connected to the first semiconductor chip 110 via the re-wiring layer 150 extending on the upper surfaces of the first semiconductor chip 110 and the first encapsulating material layer 120. In an embodiment, the connection pads 130 and the re-wiring layer 150 may be simultaneously formed by patterning a deposited metal material layer.

A dielectric layer 300 may be formed on the semiconductor chip package unit 100 to cover a portion of the upper surfaces of the first semiconductor chip 110 and a portion of the first encapsulating material layer 120 and to expose the plurality of connection pads 130 (Operation S1508).

Next, the prepared semiconductor chip package unit 100 may be disposed on a substrate 10. The substrate 10 may be a PCB or the like as described above with the external connection member 20 provided on a lower surface thereof. The semiconductor chip package unit 100 may be disposed on an upper surface of the substrate 10 by using an adhesive layer.

Next, a second semiconductor chip 200 may be stacked on the upper surface of the semiconductor chip package unit 100 (Operation S1520). In one embodiment, the second semiconductor chip 200 may be attached on the semiconductor chip package unit 100 via an adhesive layer. The second semiconductor chip 200 may be stacked on the semiconductor chip package unit 100 in an offset manner, thereby exposing the connection pads 130 on a portion of the upper surface of the semiconductor chip package unit 100, which is adjacent to one side of the first semiconductor chip 110. However, in other embodiments, the second semiconductor chip 200 may be stacked in other manners. For example, the second semiconductor chip 200 may be stacked closer to a center of the upper surface of the semiconductor chip package unit 100 and may expose connection pads 130 formed on a portion of the upper surface of the first encapsulating material layer 120, the portion surrounding the first semiconductor chip 110.

After the second semiconductor chip 200 is stacked, the second semiconductor chip 200 may be electrically connected to at least one of the connection pads 130, which is connected to the first semiconductor chip 110 (Operation S1530). In an embodiment, the second semiconductor chip 200 may be electrically connected to a first connection pad 130-1 that is electrically connected to the first semiconductor chip 110 through a bonding wire 320 or a conductive adhesive 330. In other embodiments, a second semiconductor chip 200-2 may be stacked on an upper surface of a second semiconductor chip 200-1, as illustrated in FIG. 5. The second semiconductor chip 200-2 may be electrically connected to the second semiconductor chip 200-1 through a connection member 245 of the second semiconductor chip 200-1 under the second semiconductor chip 200-2, and the second semiconductor chip 200-1 may be electrically connected to the first semiconductor chip 110 through a connection member 245 of the first semiconductor chip 110 under the second semiconductor chip 200-1. Accordingly, the second semiconductor chips 200-1 and 200-2 may receive the same electrical signal from the first semiconductor chip 110.

In an embodiment, the connection pads 130 may include a first connection pad 130-1, a second connection pad 130-2, and a third connection pad 130-3. Bonding wires 320 may be used to electrically connect the second semiconductor chip 200 to the first connection pad 130-1, thereby electrically connecting the first semiconductor chip 110 and the second semiconductor chip 200 to each other through the first connection pad 130-1, to electrically connect the second connection pad 130-2 to the substrate 10, thereby electrically connecting the first semiconductor chip 110 and the substrate 10 to each other through the second connection pad 130-2, and to electrically connect the second semiconductor chip 200 to the third connection pad 130-3, thereby electrically connecting the second semiconductor chip 200 and the substrate 10 to each other through the third connection pad 130-3. However, in other embodiments, an electrical connection member such as the conductive adhesive 330 may also be used.

A second encapsulating material layer 310 may be formed on the substrate 10 to cover the semiconductor chip package unit 100 and the second semiconductor chip 200 (Operation S1540). The second encapsulating material layer 310 may protect the substrate 10, the semiconductor chip package unit 100, and the second semiconductor chip 200 from an external environment such as moisture, impurities and the like. In an embodiment, the second encapsulating material layer 310 may, but need not be formed of the same material as that of the first encapsulating material layer 120. The second encapsulating material layer 310 may be formed by an injection molding process. In one embodiment, the second encapsulating material layer 310 may be formed using the same encapsulating process generally used to form a semiconductor package.

A semiconductor package according to any one of the above embodiments may form a signal path between the first semiconductor chip 110 (e.g., a memory controller chip) in the semiconductor chip package unit 100 and the second semiconductor chip 200 (e.g., a NAND flash memory chip) stacked on the semiconductor chip package unit 100 by using the connection pads 130, thereby minimizing an electrical distance of the signal path, increasing transmission speed, stabilizing signal transmission and thus improving the operation performance of a semiconductor device.

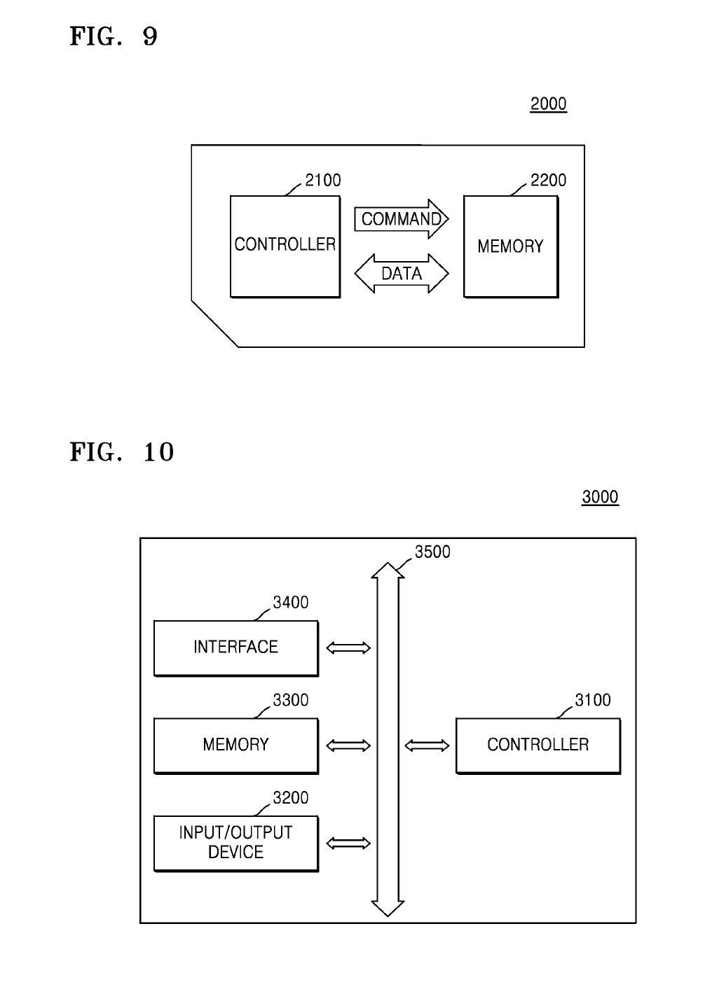

FIG. 9 is a schematic block diagram of a memory card 2000 including a semiconductor package according to an embodiment. Referring to FIG. 9, in the memory card 2000, a controller 2100 and a memory 2200 may be arranged and electrical signals are exchanged therebetween. For example, when the controller 2100 transmits an instruction, the memory 2200 may transmit data. The controller 2100 and/or the memory 2200 may include a semiconductor package according to any one of the embodiments. In a particular embodiment, the controller 2100 may include the first semiconductor chip 110 in the semiconductor package 1000, 1100, 1200, 1300, or 1400 according to any one of the embodiments, and the memory 220 may include the second semiconductor chip 200 in the semiconductor package 1000, 1100, 1200, 1300, or 1400. However, in other embodiments, the controller 2100 alone may include a semiconductor package as described herein, and/or the memory 2200 alone may include a semiconductor package as described herein.

The memory card 2000 may be part of various memory apparatuses such as various types of cards, e.g., a memory stick card, a smart media (SM) card, a secure digital (SD) card, a mini SD card, a multi-media card (MMC), or the like.

FIG. 10 is a block diagram of an electronic system 3000 including a semiconductor package according to an embodiment. Referring to FIG. 10, the electronic system 3000 may include a controller 3100, an input/output device 3200, a memory 3300, and an interface 3400. The electronic system 3000 may be a mobile system or a system for transmitting or receiving information. The mobile system may be a personal digital assistant (PDA), a portable computer, a web tablet, a wireless phone, a mobile phone, a digital music player, or a memory card.

The controller 3100 may be configured to function to execute a program and to control the electronic system 3000. The controller 3100 may be, for example, a microprocessor, a digital signal processor, a microcontroller, a programmable logic device, combinations of such devices, or the like. The input/output device 3200 may be configured to input or output data to or from the electronic system 3000.

The electronic system 3000 may be configured to exchange data with an external device, e.g., a personal computer (PC) or a network, by connecting to the external device using the input/output device 3200. The input/output device 3200 may be, for example, a keypad, a keyboard, a display, network interface, or the like. The memory 3300 may be configured to store codes and/or data for an operation of the controller 3100 and/or store data processed by the controller 3100. The controller 3100, the memory 3300, the input/output device 3200, and/or the interface 3400 may include the semiconductor package 1000, 1100, 1200, 1300, or 1400 according to any one of the embodiments. For example, the controller 3100 may include the first semiconductor chip 110 in the semiconductor package 1000, 1100, 1200, 1300, or 1400 according to any one of the embodiments, and the memory 3300 may include the second semiconductor chip 200 in the semiconductor package 1000, 1100, 1200, 1300, or 1400 according to any one of the embodiments. In other examples, the semiconductor package according to an embodiment may include multiple components of the system 3000, single components of the system 3000, or the like. The interface 3400 may be a data transmission path between the electronic system 3000 and an external device. The controller 3100, the input/output device 3200, the memory 3300, and the interface 3400 may communicate with each other via a bus 3500.

For example, the electronic system 3000 may be used in mobile phones, MP3 players, navigation machines, portable multimedia players (PMPs), solid state disks (SSDs), household appliances, or the like.

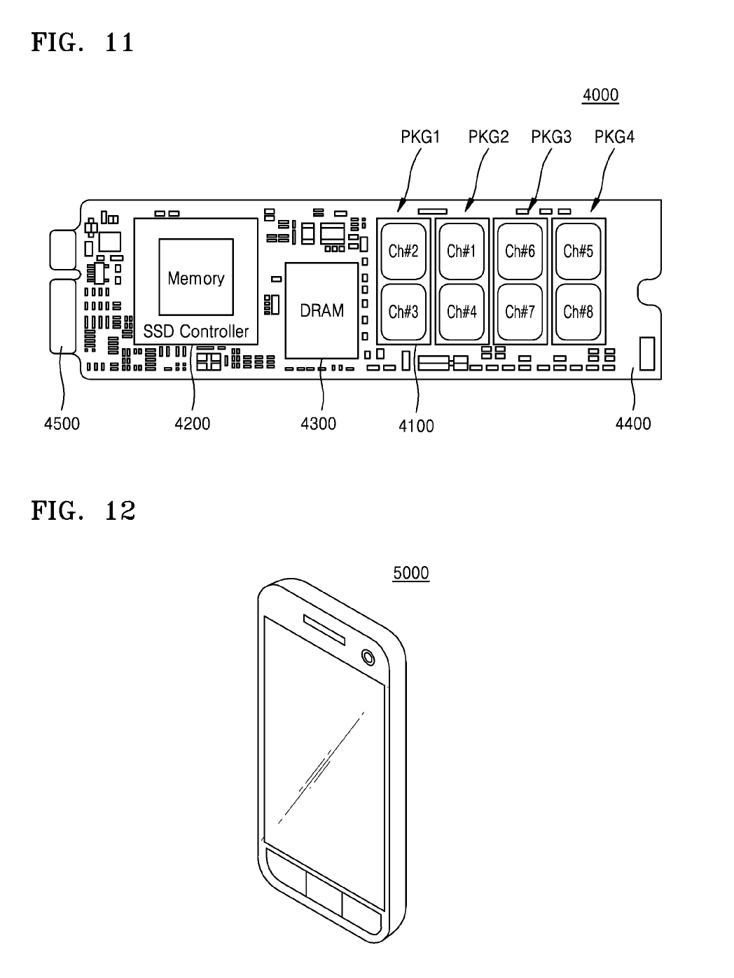

FIG. 11 is a top view of a solid state drive (SSD) device 4000 to which a semiconductor package according to an embodiment is applied. In an embodiment, the memory card 2000 of FIG. 9 may be part of the SSD device 4000. Referring to FIG. 11, the SSD device 4000 may include memory packages 4100, an SSD controller package 4200, DRAM 4300, and a main board 4400.

The memory packages 4100, the SSD controller package 4200, and the DRAM 4300 may include the semiconductor package 1000, 1100, 1200, 1300, or 1400 according to any one of the embodiments. The memory package 4100 may be mounted on the main board 4400 through an external connection member (such as the external connection member 20 of FIG. 1), and as shown in FIG. 11, the memory packages 4100 may include four memory packages PKG1, PKG2, PKG3, and PKG4. However, embodiments are not limited to four memory packages 4100, and the memory packages 4100 may include more or less than four memory packages according to a channel support state of the SSD controller package 4200. In a particular embodiment, when a memory package 4100 is configured with multiple channels, the memory package 4100 may include three or less memory packages.

The memory package 4100 may be mounted on the main board 4400 in a ball grid array (BGA) method through an external connection member, such as a solder ball. However, embodiments are not limited to such mounting techniques, and the memory package 4100 may be mounted on the main board 4400 by other methods. For example, the memory package 4100 may be mounted on the main board 4400 in a PGA method, an MPGA method, a tape carrier package (TCP) method, a chip-on-board (COB) method, a quad flat non-leaded (QFN) method, a quad flat package (QFP) method, or the like.

The memory package 4100 may include at least one of the semiconductor packages 1000, 1100, 1200, 1300, and 1400 according to the embodiments.

The SSD controller package 4200 may include eight channels, and the eight channels may be one-to-one connected to corresponding channels of the four memory packages PKG1, PKG2, PKG3, and PKG4 to thereby control semiconductor chips in the memory package 4100.

The SSD controller package 4200 may include a program capable of transmitting or receiving signals to or from an external device in a method based on the serial advanced technology attachment (SATA) standard, the parallel advanced technology attachment (PATA) standard, the small computer system interface (SCSI) standard, or the like. The SATA standard may include all SATA-group standards, such as SATA-1, SATA-2, SATA-3, external SATA (e-SATA), and the like. The PATA standard may include all integrated drive electronics (IDE)-group standards, such as IDE, enhanced IDE (E-IDE), and the like.

The SSD controller package 4200 may be in charge of EEC or FTL processing. The SSD controller package 4200 may also be mounted on the main board 4400 in a package form. Like the memory package 4100, the SSD controller package 4200 may be mounted on the main board 4400 in a BGA method, a PGA method, an MPGA method, a TCP method, a COB method, a QFN method, a QFP method, or the like.

The SSD controller package 4200 may include at least one of the semiconductor packages 1000, 1100, 1200, 1300, and 1400 according to the embodiments.

The DRAM 4300 is an auxiliary memory device and may function as a buffer in a data exchange between the SSD controller package 4200 and the memory package 4100. The DRAM 4300 may also be mounted on the main board 4400 in various methods, such as a BGA method, a PGA method, an MPGA method, a TCP method, a COB method, a QFN method, a QFP method, and the like.

The main board 4400 may be a PCB, a flexible PCB, an organic substrate, a ceramic substrate, a tape substrate, or the like. The main board 4400 may include, for example, a core board having an upper surface and a lower surface and resin layers respectively formed on the upper surface and the lower surface. The resin layers may be formed in a multi-layer structure, and a signal layer, a ground layer, or a power layer, which forms a wiring pattern, may be interposed in the multi-layer structure. A separate wiring pattern may be formed on the resin layers. In FIG. 11, minute patterns on the main board 4400 may indicate wiring patterns or multiple passive or active elements. An interface 4500 for communicating with an external device may be formed on one side, e.g., the left side, of the main board 4400.

FIG. 12 is a perspective view of an electronic device to which a semiconductor package according to an embodiment is applied. FIG. 12 is an example in which the electronic system 3000 of FIG. 10 is part of a mobile phone 5000. Although a mobile phone 5000 has been used as an example, the electronic system 3000 may be used in other devices and systems such as portable laptop computers, MP3 players, navigation systems, SSDs, vehicles, household appliances, or the like. In addition, the electronic system 3000 may be part of any communication device.

While embodiments have been particularly shown and described with reference to particular embodiments, it will be understood that various changes in form and details may be made therein without departing from the spirit and scope of the following claims.

What is claimed is:

1. A semiconductor package comprising:
a substrate;
a semiconductor chip package unit disposed on the substrate, the semiconductor chip package unit comprising:
a first semiconductor chip;
a first encapsulating material layer encapsulating the first semiconductor chip;
connection pads formed on an upper surface of the first encapsulating material layer, at least one of the connection pads being electrically connected to the first semiconductor chip; and
a re-wiring layer extending on an upper surface of the semiconductor chip and the upper surface of the first encapsulating material layer, the re-wiring layer being electrically connected to the first semiconductor chip and at least one of the connection pads; and
a second semiconductor chip stacked on an upper surface of the semiconductor chip package unit, wherein the second semiconductor chip exposes the connection pads and is electrically connected to one or more of the at least one of the connection pads electrically connected to the first semiconductor chip.

2. The semiconductor package of claim 1, wherein the second semiconductor chip disposed such that a side of the first semiconductor chip is not aligned with a side of the second semiconductor chip.

3. The semiconductor package of claim 1, further comprising a connection member formed at the upper surface of the first semiconductor chip, the connection member being connected to the re-wiring layer.

4. The semiconductor package of claim 1, further comprising a dielectric layer covering at least a portion of the upper surface of the first semiconductor chip and at least a portion of the upper surface of the first encapsulating material layer and exposing the connection pads.

5. The semiconductor package of claim 1, further comprising a third semiconductor chip stacked on the second semiconductor chip, wherein the third semiconductor chip exposes a connection member of the second semiconductor chip and is electrically connected to the connection member of the second semiconductor chip and the first semiconductor chip.

6. The semiconductor package of claim 5, wherein the second semiconductor chip and the third semiconductor chip are configured to receive substantially the same signals from the first semiconductor chip.

7. The semiconductor package of claim 1, wherein the connection pads comprise:
a first connection pad, to which the first semiconductor chip and the second semiconductor chip are electrically connected, such that the first semiconductor chip and the second semiconductor chip are electrically connected to each other through the first pad;
a second connection pad, to which the first semiconductor chip and the substrate are electrically connected, such that the first semiconductor chip and the substrate are electrically connected to each other through the second pad; and
a third connection pad, to which the second semiconductor chip and the substrate are electrically connected, such that the second semiconductor chip and the substrate are electrically connected to each other through the third pad.

8. The semiconductor package of claim 7, further comprising at least one bonding wire electrically connecting the first and third connection pads to the second semiconductor chip.

9. The semiconductor package of claim 8, wherein the at least one bonding wire electrically connects the second connection pad and the third connection pad to the substrate.

10. The semiconductor package of claim 1, further comprising a second encapsulating material layer encapsulating an upper surface of the substrate, the semiconductor chip package unit, and the second semiconductor chip.

11. The semiconductor package of claim 1, wherein the second semiconductor chip is electrically connected to the substrate through at least one of the connection pads.

12. The semiconductor package of claim 1, wherein the upper surface of the first encapsulating material layer and the upper surface of the first semiconductor chip are substantially coplanar.

13. A semiconductor package comprising:
a substrate having an external connection terminal disposed on a lower surface of the substrate;
a semiconductor chip package unit disposed on the substrate, the first semiconductor chip package unit comprising:
a first semiconductor chip;
a first encapsulating material layer encapsulating the first semiconductor chip; and
a plurality of connection pads disposed at a side portion of an upper surface of the first encapsulating material layer and that are electrically connected to the first semiconductor chip, the side portion being adjacent to a side of the first semiconductor chip; and
at least one second semiconductor chip stacked on an upper surface of the semiconductor chip package unit, wherein the at least one second semiconductor chip exposes the side portion of the upper surface of the first encapsulating material layer and is connected to the connection pads.

14. The semiconductor package of claim 13, further comprising a second encapsulating material layer that encapsulates an upper surface of the substrate, the semiconductor chip package unit, and the second semiconductor chip.

15. The semiconductor package of claim 13, wherein the first semiconductor chip is a memory controller chip and the at least one second semiconductor chip is a NAND flash memory chip.

16. The semiconductor package of claim 13, further comprising a bonding wire electrically connecting the connection pads to the at least one second semiconductor chip or the substrate.

17. The semiconductor package of claim 13, wherein the at least one second semiconductor chip is electrically connected to a connection member of the first semiconductor chip disposed under the at least one second semiconductor chip.

18. A semiconductor package, comprising:
a substrate;
a semiconductor chip package unit disposed on the substrate, the first semiconductor chip package unit comprising:
a plurality of first semiconductor chips, each first semiconductor chip including a connection member;
a first encapsulating material layer encapsulating the first semiconductor chips;
a plurality of connection pads; and
a re-wiring layer electrically connecting the first semiconductor chips to each other and to the connection pads; and
a second semiconductor chip disposed on the semiconductor chip package unit such that the connection pads are exposed, wherein the second semiconductor chip is electrically connected to the connection pads.

19. The semiconductor package of claim 18, wherein at least one of the first semiconductor chips is electrically connected to the connection pads only through another first semiconductor chip of the first semiconductor chips.

20. The semiconductor package of claim 18, further comprising:
a dielectric layer covering each of the plurality of first semiconductor chips;
wherein the second semiconductor chip is disposed on the dielectric layer.
